(19) United States
(12) Patent Application Publication
(10) Pub. No.: US 2011/0012140 A1
(43) Pub. Date: Jan. 20, 2011

(54) LIGHT EMITTING DIODE ARRANGEMENT

(75) Inventor: Stefan Peter Grabowski, Neuss (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/934,684

(22) PCT Filed: Mar. 30, 2009
(86) PCT No.: PCT/IB2009/051305

§ 371 Date: Sep. 27, 2010

(30) Foreign Application Priority Data
Apr. 2, 2008 (EP) 08103309.4

(51) Int. Cl. H01L 33/00

(52) U.S. Cl. 257/88; 257/E33.001

(57) ABSTRACT

The invention relates to a light emitting diode arrangement comprising a first light emitting diode (101), in particular an organic light emitting diode, comprising a first light emitting layer (105) and a first electrode (109) arranged on the first light emitting layer (105), and a second light emitting diode (103), in particular an organic light emitting diode, being arranged upon the first light emitting diode (101), the second light emitting diode (103) comprising a second light emitting layer (113) and a second electrode (117) arranged on the second light emitting layer (113), the second electrode (117) being translucent.

### FIELD OF THE INVENTION

The present invention relates to light emitting diodes, in particular to organic light emitting diodes.

### BACKGROUND OF THE INVENTION

Light emitting diodes, in particular organic light emitting diodes (OLEDs) are suitable not only for displaying or illuminating but may also be employed for signaling information in form of e.g. a lightening sign being determined by a light emitting pattern. However, the known light emitting diodes enable emitting of only one pattern e.g. representing a certain information in one direction. Thus, such a light emitting diode may only be employed as a conventional sign. In order to emit different patterns representing different information, complex display devices may be employed, like e.g. liquid crystal displays. However, display devices are more expensive and require additional control devices.

The US 2005/0057149 A1 discloses a display electronic device having two OLED displays arranged on opposite sides of one of the same port of the device, the first display showing information mainly in a first direction, the second display showing information in a second direction opposite from the first direction.

### SUMMARY OF THE INVENTION

It is the object of the invention to provide a light emitting diode arrangement being capable of emitting different patterns in the same direction.

This object is achieved by the features of the independent claims.

The invention is based on the finding that the above identified problem may be solved by arranging at least two light emitting diodes upon each other, wherein at least one of the light emitting diodes is translucent with respect to emitted light of the other light emitting diode. Thus, if the light emitting diodes are e.g. stacked over each other then the light emitted by a first diode may pass translucent structures forming the second diode arranged e.g. above the first diode so that a light pattern associated with the first diode or a certain color emitted by the first diode is visible. Thus, in order to display a plurality of colors or patterns in the same direction, a plurality of translucent diodes may be employed which preferably are organic light emitting diodes, by way of example. The plurality of light emitting diodes may be glued together using e.g. transparent adhesives so that the manufacturing process is simple and chip.

The advantage of the inventive concept with respect to pixel oriented displays is that light emitting areas and not light emitting pixels are provided. For example a red stop sign may be provided which emits light over the entire area of interest without pixel based irregularities. In order to achieve the corresponding effect with display based devices, a fine pixel distribution with a high resolution is necessary which is, however, expensive.

The invention relates to a light emitting diode arrangement comprising a first light emitting diode, in particular an organic light emitting diode, comprising a first light emitting layer and a first electrode, e.g. a top electrode, arranged on the first light emitting layer, and a second light emitting diode, in particular an organic light emitting diode, being arranged upon the first light emitting diode, the second light emitting diode comprising a second light emitting layer and a second electrode, e.g. a top electrode arranged on the light emitting layer, the second electrode being transparent. Furthermore, a first bottom electrode arranged on the first substrate and a second bottom electrode arranged on the second substrate may be provided.

According to an embodiment, the first electrode arranged on the first light emitting layer is transparent or non-transparent.

According to an embodiment, the first light emitting layer emits light of a first wavelength and the second light emits layer emitting light of a second wavelength which is different from the first wavelength.

According to an embodiment, the first light emitting layer is arranged on a first substrate, the second light emitting layer on a second substrate, the first substrate and the second substrate being transparent.

According to an embodiment, the first light emitting layer and the second light emitting layer are arranged above opposite sides of a common substrate or the first light emitting layer is arranged above a first surface of a first substrate, the second light emitting layer is arranged above a second surface of a second substrate wherein a second surface of the first substrate opposes, in particular connects to, a second surface or the second substrate.

According to an embodiment, the first diode comprises a first transparent seal element having a first surface facing the first light emitting layer, the second diode comprises a second transparent seal element having a first surface facing the second light emitting layer, a second surface of the first transparent seal element opposing, in particular connecting to, a second surface or the second transparent seal element.

According to an embodiment, the first light emitting layer is arranged on a first substrate electrode, the second light emitting layer is arranged on a second substrate electrode, the first substrate electrode having a shape corresponding to a light pattern being emittable by the first light emitting diode, the second substrate diode having a shape corresponding to a light emitting pattern being emittable by the second light emitting diode.

According to an embodiment, the first light emitting layer is arranged on a first substrate electrode, the second light emitting layer is arranged on a second substrate electrode, the first substrate electrode and the second substrate electrode at least partly extending over the respective light emitting layer, the first substrate electrode and the second substrate being arranged so as to provide non-overlapping portions for enabling independently contacting to the first substrate electrode and to the second substrate electrode.

According to an embodiment, the light emitting diode arrangement comprises a plurality of light emitting diodes being arranged upon each other, an outer diode of the plurality of diodes comprising a non-transparent electrode arranged on a light emitting layer, each other diode comprising a transparent electrode respectively arranged on a light emitting layer.

The invention further relates to a method for manufacturing a light emitting diode arrangement. The method comprises manufacturing a first light emitting diode, in particular an organic light emitting diode, comprising a first light emitting layer and a first electrode arranged on the first light emitting layer and manufacturing a second light emitting diode, in particular an organic light emitting diode, upon the first light emitting diode, the second light emitting diode comprising a second light emitting layer and a second electrode arranged on the light emitting layer, the second electrode being transparent.

### BRIEF DESCRIPTION OF THE DRAWINGS

Further embodiments of the invention will be described in the following with respect to the accompanying figures, in which:

FIG. 1 shows a light emitting diode arrangement,

FIGS. 2a and 2b show different patterns emitted by a light emitting diode arrangement; and

FIG. 3 shows a light emitting diode arrangement.

### DETAILED DESCRIPTION OF EMBODIMENTS

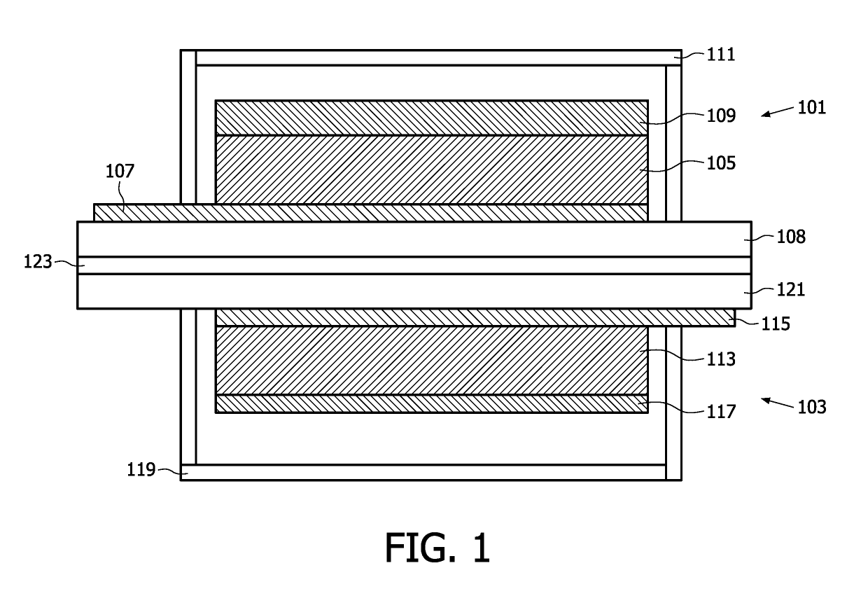

FIG. 1 discloses a light emitting diode arrangement comprising a first diode 101 and a second diode 103. The first diode comprises one or more light emitting layers 105, e.g. organic light emitting layers, which are arranged on a substrate layer 108. Further, a first electrode 107 is provided on the substrate layer 108 and a second electrode 109 is provided on a surface of the light emitting layer 105. The first diode 101 may be sealed with a cover 111.

The second light emitting diode 103 is arranged upon the first light emitting diode 101 and correspondingly comprises one or more light emitting layers 113, e.g. organic light emitting layers, which are arranged on a substrate electrode 115. The light emitting layers 113 are covered by an electrode 117, wherein a cover 119 is provided so as to seal or cover the second light emitting diode. The substrate electrode 115 is arranged on a substrate 121. As depicted in FIG. 1, the substrates 108 and 121 are arranged back to back, wherein an adhesive layer 123 may be provided. However, the first diode 101 and the second diode 103 may be provided on opposite sides of the same layer which may be transparent.

The first diode and the second diode 101, 103 may be organic light emitting diodes emitting the same light spectrum or different light spectra.

The substrates 108 and 121 or a common substrate forming these substrates may be transparent with respect to light and may comprise glass or transparent plastic material. The substrate electrodes 107 and 115 may be translucent and conductive and may be arranged to form bottom electrodes. The substrate electrodes 107 and 115 may consist of indium tin oxide (ITO), by way of example. The light emitting layer 105 and 113 may be organic, wherein the electrode 109 covering the light emitting layer 105 associated with the first diode 101 may be made of vaporizated aluminum, by way of example. The covers 111 and 119 protect the respective diode from being exposed to air. Further, the cover 111 and the cover 119 may comprise a getter material for absorbing moisture.

The second diode 103 may be configured to emit light of a different wavelength than the first diode 101, e.g. to emit green light. In difference to the first diode 101, the second light emitting diode 103 is translucent, i.e. transparent with respect to light which is emitted by the first diode or the second diode. The top electrode 117 of the second diode 103 is preferably translucent and consists of a thin, transparent metal film of silver or aluminum, by way of example. Furthermore, the cover 119 also is translucent.

The first and the second diode 101, and 103 are by way of example connected via the adhesive layer 123 comprising a refraction index corresponding to a refraction index of the substrate 121 or of the substrate 108, by way of example. Furthermore, the diodes 101 and 103 are arranged so that the respective bottom electrodes 107 and 115 may independently be contacted. As depicted in FIG. 1, the bottom electrodes 107 and 115 comprise none overlapping portions which may be achieved by displacing this electrode with respect to each other.

According to an aspect, the bottom electrodes 107 and 115 may have different structures defining a pattern to be emitted by the respective diode 101 and 103.

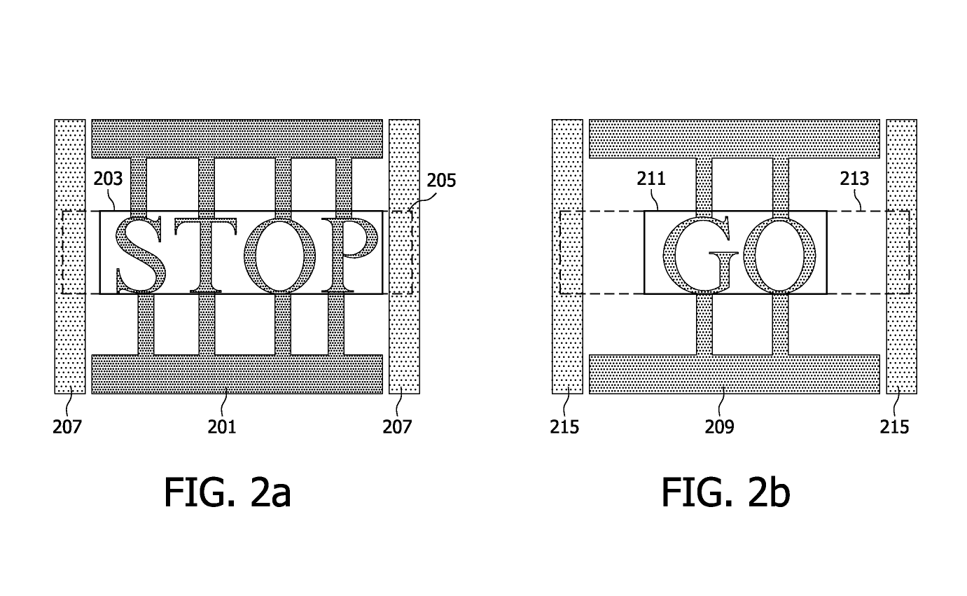

FIGS. 2A and 2B show, by way of example, different shapes of bottom electrodes producing light patterns forming the term “stop” or “go”, respectively.

FIG. 2A depicts by way of example a structure of a bottom electrode 201 which may form the bottom electrode 107 of the first diode 101. The electrode 201 may be e.g. an ITO electrode being structured so as to form a certain sign or a certain symbol. The ITO electrode 201 is covered by a translucent light emitting, organic layer 203 and a top electrode 205 corresponding to the electrode 109 of the first diode 101. Further, contact areas 207 for contacting to the top electrode 205 are provided outside the lightening area.

FIG. 2B correspondingly shows a light emitting diode which may form the second light emitting diode 103 of FIG. 1. Correspondingly, the light emitting diode comprises a transparent ITO electrode 209 corresponding to the electrode 115 of FIG. 1 being formed to provide a shape of a sign or of a symbol. The bottom ITO electrode 209 is covered by a light emitting, organic layer 211 corresponding to the layer 113 of FIG. 1 which is covered by a top electrode 213 corresponding to the electrode which may be contacted via contacting areas 215 which are arranged outside the light emitting area.

As depicted in FIGS. 2A and 2B, the respective bottom electrode 201 and 209 may be respectively contacted by the contact areas 207 and 215 which are arranged side wards the respective bottom electrode 201 and 209 and which may comprise a metal film. The organic layers 203 and 211 are preferably arranged above the structured area of the respective bottom electrodes 201 and 209. However, the organic layers 203 and 211 may also be arranged to form the structured pattern of the respective bottom electrodes 201 and 209. According to an aspect, the organic layers 203 and 211 may be arranged to form rectangular areas since the organic layers 203 and 211 are mainly excited in the areas between the electrodes.

The bottom electrodes 201 and 209 may be arranged to form different shapes so as to provide different words, signs, numbers or symbols. For example, the stop sign may be red wherein the go sign may be green. Furthermore, walking or resting pedestrians, a stop sign, a green arrow, arrows pointing in certain direction for e.g. visitors in buildings may be provided.

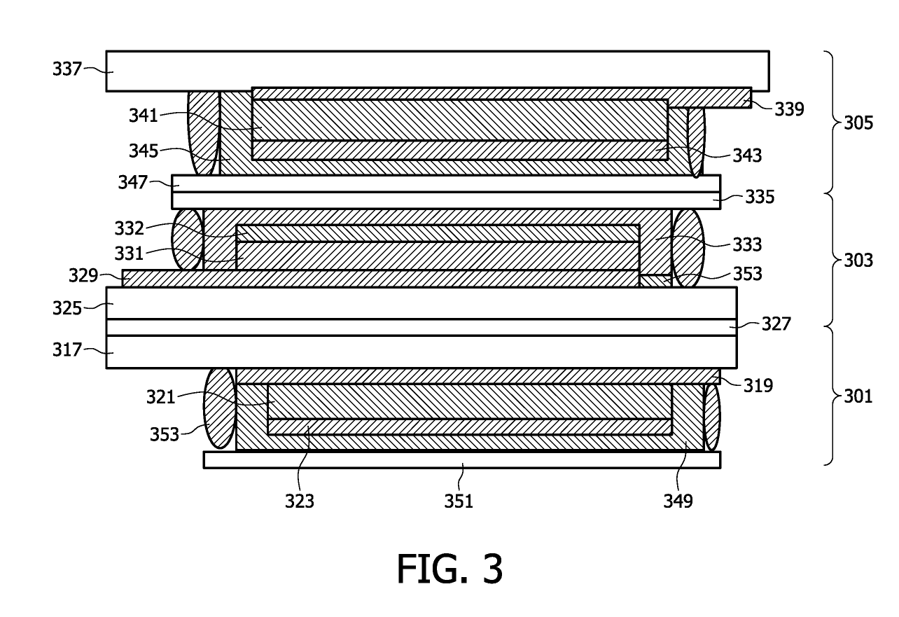

FIG. 3 depicts a plurality of light emitting diodes, e.g. organic light emitting diodes, which are arranged upon each other. By way of example, a first light emitting diode 301, a second light emitting diode 303 and a third light emitting diode 305 are provided.

The diodes depicted in FIG. 3 may be OLEDs which are stacked over each other in order to display more information. That case, preferably all light emitting diodes except one of the outmost OLEDs are transparent.

The diodes depicted in FIG. 3 correspond to the diodes depicted in FIG. 1. Thus, a first diode 301 comprises a substrate 317, a substrate electrode 319 arranged on the substrate 317, a light emitting layer 321 arranged on the substrate electrode 319 and a top electrode 323 arranged on the preferably organic light emitting layer 321.

The second light emitting diode 303 correspondingly comprises a substrate 325 being arranged on a surface of the substrate 317 to form a back-to-back structure, wherein an adhesive layer 327 may further be provided. Onto the substrate 325, a substrate electrode 329 is provided onto which a preferably organic light emitting layer 331 is arranged. Furthermore, a top electrode 332 arranged on a surface of the light emitting layer 331 is provided.

The light emitting layer 331 and the light top electrode 332 are sealed by a thin film encapsulation 333 onto which e.g. a transparent glass cover 335 is provided.

The third light emitting diode 305 correspondingly comprises a substrate layer 337 onto which a substrate electrode 339 is arranged. A light emitting layer 341 is arranged on the substrate electrode 339 and covered by a top electrode 343. Furthermore, the light emitting layer 341 and the top electrode 343 and at least a portion of the bottom electrode 339 are sealed with a thin film insulating layer 345. Onto the thin film layer 345, a transparent cover is provided. The second diode 303 and the third diode 305 are arranged so that the transparent covers 335 and 347 contact to each other.

The first diode 301 is accordingly sealed and comprise a thin film cover 349 sealing the light emitting layer 321 and the top electrode 323, wherein a transparent cover 351 is provided. By way of example, the second diode 303 may comprise a displacement portion 353 for compensating for the displacement of the substrate electrode 329 in order to seal the same. The electrodes 339, 329 and 319 are arranged so as to enable independently contacting to each of these electrodes. Further, sealing portions 353 sidewardly sealing each diodes 301, 303 and 305 are provided.

The thin film encapsulations 345, 333 and 349 are arranged to easify stacking the respective diodes. Each thin film cover may form a water tight film. Furthermore, a glass cover may be used for encapsulation purposes. Such a glass cover may be mounted on the respective OLED using an adhesive comprising a getter material. Furthermore, an impermeable adhesive can be arranged around the adhesive area which does not comprise any getter material. Alternatively, the respective glass cover may be adhered to the respective OLED using at least two adhesive frames. Furthermore, by way of example, the inner adhesive strip may contain a getter material whereas the outer adhesive strip does not contain any getter material, by way of example.

1. Light emitting diode arrangement, comprising:
a first organic light emitting diode, comprising a first light emitting layer arranged on a first substrate electrode and a non-translucent first electrode arranged on the first light emitting layer; and
a second organic light emitting diode, being arranged upon the first light emitting diode, the second light emitting diode comprising a second light emitting layer arranged on a second substrate electrode and a translucent second electrode arranged on the second light emitting layer, wherein.
the first substrate electrode has a shape corresponding to a light pattern emittable by the first light emitting diode and is arranged on a first substrate,
the second substrate electrode has a shape corresponding to a light pattern emittable by the second light emitting diode and is arranged on a second substrate, and
an adhesive layer is provided between said first substrate and said second substrate.

2. (canceled)

3. The light emitting diode arrangement according to claim 1, the first light emitting layer emitting light of a first wavelength, the second light emitting layer emitting light of a second wavelength different from the first wavelength.

4. The light emitting diode arrangement according to claim 1, wherein the first substrate and the second substrate are transparent.

5. (canceled)

6. The light emitting diode arrangement according to claim 1, the first diode comprising a first transparent seal element having a first surface facing the first light emitting layer, the second diode comprising a second transparent seal element having a first surface facing the second light emitting layer, a second surface of the first transparent seal element opposing and connecting to, a second surface or the second transparent seal element.

7. (canceled)

8. The light emitting diode arrangement according to claim 1, the first light emitting layer being arranged on a first substrate electrode, the second light emitting layer being arranged on a second substrate electrode, the first substrate electrode and the second substrate electrode at least partly extending over the respective light emitting layer, the first substrate electrode and the second substrate being arranged so as to provide non-overlapping portions for enabling independently contacting to the first substrate electrode or to the second substrate electrode.

9. The light emitting diode arrangement according to claim 1, comprising a plurality of light emitting diodes being arranged upon each other, an outer diode of the plurality of diodes comprising a non-transparent electrode arranged on a light emitting layer, each other diode comprising a transparent electrode respectively arranged on a light emitting layer.

10. (canceled)
